(19) United States
(12) Patent Application Publication
(10) Pub. No.: US 2004/0082089 A1
(43) Pub. Date: Apr. 29, 2004

(54) OLED PACKAGE AND METHOD FOR FABRICATING THE SAME

(76) Inventors: Tung-Sheng Cheng, Hsinchu (TW); Yu-Kai Han, Taipei (TW); Yen-Hua Lin, Hsinchu (TW); Pei-Chuan Yeh, Miaoli (TW); Hsia-Tsai Hsiao, Miaoli (TW); Jerry Yen, Hsinchu (TW); Chia-Liang Peng, Hsinchu (TW); Yi-Fan Su, Changhua City (TW)

Correspondence Address: JIANQ CHYUN INTELLECTUAL PROPERTY OFFICE, 7 FLOOR-1, NO. 100, ROOSEVELT ROAD, SECTION 2, TAIPEI, 100, TW

(21) Appl. No.: 10/249,498

(22) Filed: Apr. 15, 2003

(30) Foreign Application Priority Data
Oct. 25, 2002 (TW) 91125122

(51) Int. Cl. H01L 21/00

(52) U.S. Cl. 438/26

(57) ABSTRACT

An organic light-emitting device having a porous desiccant layer therein and a method for fabricating the same is provided. The porous desiccant layer is manufactured by spreading a liquid desiccant on a surface, forming air bubbles (by activating some vesicant or injecting gas into the liquid desiccant) and curing the liquid desiccant. The porous desiccant comprises solidified hardening glue having bubbles and lots of desiccant particles or powder distributed evenly therein. Some residual vesicant may remain inside the solidified hardening glue after activation. The bubbles inside the porous desiccant enhance the absorption rate and efficiency of the desiccant so that moisture and gaseous oxygen inside the OLED package can be absorbed rapidly.

### CROSS REFERENCE TO RELATED APPLICATIONS

This application claims the priority benefit of Taiwan application serial No. 91125122, filed Oct. 25, 2002.

### BACKGROUND OF INVENTION

1. Field of Invention

The present invention relates to an organic light-emitting device (OLED) or organic electro-luminescent (OEL) package structure and corresponding method of fabrication. More particularly, the present invention relates to an OLED package containing porous desiccant and method for fabricating the same.

2. Description of Related Art

The development of various portable communication equipment and display products has lead to a fast growth in the information processing industry. Flat panel display is now a convenient human/machine interface for communication. The types of technologies suitable for producing a flat panel display includes plasma display panel (PDP), liquid crystal display (LCD), electro-luminescent display, light-emitting diode (LED), vacuum fluorescent display, field emission display (FED), electro-chromic display and so on.

Comparing with various other types of technologies for producing flat panel displays, organic light-emitting device (OLED) is a self-illuminating, viewing angle free and energy saving device. Combined with other advantages such as a low production cost, easy to manufacture, a low operating temperature, fast response and full coloration, OLED has the greatest potential to become a mainstream product in the next generation of flat panel display.

Organic light-emitting device is a type of display that utilizes self-illuminating organic functional materials. According to the molecular weight of the organic functional materials, OLED can be subdivided principally into small molecular organic light-emitting device (SM-OLED) and polymer light-emitting device (PLED). The light-emitting structure includes a pair of electrodes and an organic functional material therebetween. When current passes from a transparent anode and a metallic cathode, electrons and holes inside the organic functional material layer will recombine to produce excitons. Once the organic functional material is excited, the emitted color depends on the properties of the organic functional material inside the display device.

FIG. 1 is a sectional view of a conventional OLED package. The OLED package is normally performed within an inert gas. To perform an OLED package, a substrate 100 having a plurality of organic electro-luminescent films 102 thereon is provided. Sealing glue 104 is applied to the surface of the substrate 100 around the organic electro-luminescent films 102. Thereafter, a cover plate 106 is aligned with and pressed against the substrate 100. Hence, the cover plate 106, the substrate 100 and the sealing glue 104 together seal up the organic electro-luminescent films 102 within the package.

However, the sealing glue is a polymeric material, which is not a particularly effective barrier for preventing the penetration of moisture and oxygen into the sealed compartment within the package. Furthermore, the organic functional material and the cathode inside the organic electro-luminescent device structure reacts readily with moisture and oxygen leading to a shorter lifetime. Since overall lifetime of the display is largely determined by the lifetime of the OLED, proper sealing of OLED package to prevent moisture and oxygen getting into the package and reacting with the electrode and the light emitting material is important. In U.S. Pat. No. 6,226,890, a method for properly sealing an OLED package is disclosed. The invention mainly proposes the introduction of a desiccant, which comprises of a mixture of desiccant particles and binder, to absorb any moisture or oxygen into the sealed package compartment. To form the desiccant, desiccant particles are mixed with a liquid binder. The liquid desiccant is coated on the cover plate or other carrier. Finally, the liquid desiccant layer is cured to form a solid thin film.

Since some of the desiccant particles inside the solidified thin film may be sealed by the binder, moisture and oxygen can not be rapidly absorbed by the desiccant. Due to the slow absorption of moisture and oxygen inside the package at the initial stage, certain degree of damage to the OLED device may occur. Moreover, OLED device is a very thin flat panel display with very little space inside the sealed compartment. The limited space within the package for accommodating solid desiccant particles forces the desiccant to have a greater moisture/oxygen absorption capacity than other display devices. Hence, conventional solid desiccant particles used in non-planar displays can hardly meet the desiccation requirement inside an OLED package.

### SUMMARY OF INVENTION

Accordingly, one object of the present invention is to provide an organic light-emitting device (OLED) package structure and a method for fabricating the same that uses porous desiccant for increasing moisture/oxygen absorption capability and rapidity and extending the lifetime of the OLED package.

A second object of this invention is to provide a type of porous desiccant having a large contact surface so that moisture/oxygen in the sealed compartment can be absorbed rapidly and efficiently.

A third object of this invention is to provide a method of forming porous desiccant. Vesicant or some other chemicals are used to increase the number of bubbles inside the porous desiccant so that surface area for absorbing moisture and oxygen is increased.

A fourth object of this invention is to provide a method of forming porous desiccant. Through air injection or other physical method, the number of air bubbles inside the porous desiccant is increased so that surface area for absorbing moisture and oxygen is increased. Ultimately, moisture and oxygen absorbing capacity of the desiccant particles inside the porous desiccant is increased.

To achieve these and other advantages and in accordance with the purpose of the invention, as embodied and broadly described herein, this invention provides an organic light-emitting device (OLED) package structure. The OLED package mainly comprises a substrate, a cover plate, some porous desiccant and sealing glue. An organic light-emitting device is formed on the substrate. The cover plate is positioned over the substrate. The porous desiccant is attached, for example, to the cover plate. The porous desiccant comprises a mass of solidified hardening glue with many bubbles and lots of desiccant particles within the glue. In addition, the solidified hardening glue may further include some vesicant. The sealing glue is positioned between the substrate and the cover plate such that the substrate, the cover plate and the sealing glue together seal the OLED and the porous desiccant inside the package.

This invention also provides a method of forming an organic light-emitting device (OLED) package that includes the following steps: (a) providing a substrate having an organic light-emitting device thereon; (b) providing a cover plate; (c) providing a liquid desiccant, wherein the liquid desiccant contains a liquid hardening glue with a plurality of desiccant particles and some vesicant distributed uniformly within the liquid hardening glue; (d) putting some liquid desiccant on the surface of the cover plate, for example, by coating or spraying; (e) activating the vesicant inside the liquid desiccant and curing the liquid desiccant to form a layer of porous desiccant, wherein the porous desiccant comprises a mass of solidified hardening glue with many bubbles and lots of desiccant particles within the glue, in addition, the solidified hardening glue may contain some residual vesicant; and (f) applying sealing glue to the substrate and pressing the cover plate onto the substrate so that the substrate, the cover plate and the sealing glue together seal the OLED and the porous desiccant inside the package.

The invention also provides a method of manufacturing porous desiccant that includes the following steps: (a) providing a liquid desiccant comprising, for example, a liquid hardening glue and lots of desiccant particles and some vesicant distributed uniformly within the liquid hardening glue; (b) depositing the liquid desiccant onto the surface of a carrier; and (c) activating the vesicant inside the liquid desiccant so that the vesicant vesicates inside the liquid hardening glue and then curing the liquid desiccant to form porous desiccant. The porous desiccant may comprise a mass of solidified hardening glue having plenty of bubbles and lots of desiccant particles distributed evenly inside the solidified hardening glue. In addition, the solidified hardening glue may further contain some vesicants.

The edge of the aforementioned cover plate or carrier may further include at least a groove for limiting the range of distribution of the sealing glue and improving the variability of glue thickness. Consequently, bonding strength between the cover plate and the substrate as well as water-sealing capacity of the glue is increased.

In this invention, the vesicant can be liquid vesicant or solid vesicant made from material such as cyclo-pentane, fluoro-chloro-carbonate compound, dinitride compound. The vesicant is activated by heating or ultraviolet light irradiation to produce gaseous nitrogen or other inert gases. The desiccant particles are made from a material such as barium oxide (BaO) or other compound having the capacity to absorb moisture and oxygen. The liquid hardening glue is made from thermosetting plastic or an ultraviolet-setting plastic so that the liquid hardening glue can be cured into solid on heating or irradiation with ultraviolet light.

In this invention, if both the vesicant and the liquid hardening glue are activated by heating or ultraviolet irradiation, vesication of the vesicant and curing of the liquid hardening glue may be carried out simultaneously. On the other hand, if the means of vesicating the vesicant differs from the means of curing the liquid hardening glue, for example, the vesicant is activated by heating and the liquid hardening glue (an ultraviolet hardening glue) is cured by ultraviolet irradiation or vice versa, the vesicant is preferably activated before curing the liquid hardening glue.

This invention also provides an organic light-emitting device (OLED) package structure. The OLED package mainly comprises a substrate, a cover plate, some porous desiccant and sealing glue. An organic light-emitting device is formed on the substrate. The cover plate is positioned over the substrate. The porous desiccant is attached, for example, to the cover plate. The porous desiccant comprises a mass of solidified hardening glue with many bubbles and lots of desiccant particles or powder distributed evenly within the glue. The sealing glue is positioned between the substrate and the cover plate such that the substrate, the cover plate and the sealing glue together seal the OLED and the porous desiccant inside the package.

This invention also provides a method of forming an organic light-emitting device (OLED) package that includes the following steps: (a) providing a substrate having an organic light-emitting device thereon; (b) providing a cover plate; (c) providing a liquid desiccant, wherein the liquid desiccant contains a liquid hardening glue and desiccant particles or powder distributed uniformly within the liquid hardening glue; (d) putting some liquid desiccant on the surface of the cover plate, for example, by coating or spraying; (e) forming air bubbles inside the liquid desiccant by injecting air; (f) curing the liquid desiccant to form a porous desiccant layer, wherein the porous desiccant layer comprises of solidified hardening glue with plenty of bubbles therein and the desiccant particles or power distributed uniformly inside the solidified hardening glue; and (g) applying sealing glue at the junction between the substrate and the cover plate so that the substrate, the cover plate and the sealing glue together seal the OLED and the porous desiccant inside the package.

The invention also provides a method of manufacturing porous desiccant that includes the following steps: (a) providing a liquid desiccant comprising, for example, a liquid hardening glue and lots of desiccant particles or powder distributed evenly within the liquid hardening glue; (b) spreading the liquid desiccant onto the surface of a carrier; (c) forming bubbles inside the liquid desiccant by injecting air into the liquid desiccant; and (d) curing the liquid desiccant to form a porous desiccant layer, wherein the porous desiccant layer, for example, includes the solidified hardening glue with plenty of bubbles therein and the desiccant particles or powder distributed evenly within the solidified hardening glue.

This invention also provides a porous desiccant mainly comprising a solidified hardening glue with plenty of bubbles therein and lots of desiccant particles or power within the solidified hardening glue. In addition, the solidified hardening glue may contain some vesicant.

The aforementioned cover plate or carrier may further include at least a groove for limiting the spread of sealing glue so that thickness of glue is maintained at a definite range and hence bonding strength as well as wafer-sealing capacity between the cover plate and the substrate are improved.

In this invention, the desiccant particles or power is, for example, barium oxide or other material suitable for absorbing moisture and oxygen. The liquid hardening glue is, for example, thermosetting or ultraviolet setting glue such that the glue is cured into solidified hardening glue when heated or ultraviolet irradiated.

In this invention, the bubbles inside the liquid desiccant are imparted by injecting air or through some other physical means. The gas injected into the liquid desiccant is an inert gas, for example.

It is to be understood that both the foregoing general description and the following detailed description are exemplary, and are intended to provide further explanation of the invention as claimed.

### BRIEF DESCRIPTION OF DRAWINGS

The accompanying drawings are included to provide a further understanding of the invention, and are incorporated in and constitute a part of this specification. The drawings illustrate embodiments of the invention and, together with the description, serve to explain the principles of the invention. In the drawings,

FIG. 1 is a sectional view of a conventional OLED package;

FIGS. 2A to 2D are schematic views showing the steps for producing an OLED package according to a first preferred embodiment of this invention;

FIGS. 3A to 3D are schematic views showing the steps for producing an alternative OLED package together according to the first preferred embodiment of this invention;

FIG. 4 is a flow chart showing the steps for producing porous desiccant according to the first preferred embodiment of this invention;

FIG. 5 is a graph showing the relationship between moisture absorbing rate and time for desiccant in different states;

FIG. 6 is a graph showing the relationship between average size of bubble and heating time;

FIGS. 7A to 7D are schematic views showing the steps for producing an OLED package according to a second preferred embodiment of this invention;

FIGS. 8A to 8D are schematic views showing the steps for producing an alternative OLED package together according to the second preferred embodiment of this invention;

FIG. 9 is a flow chart showing the steps for producing porous desiccant according to the second preferred embodiment of this invention; and

FIGS. 10A to 10D are top views showing the locations and distribution of grooves on the cover plate of an OLED package according to this invention.

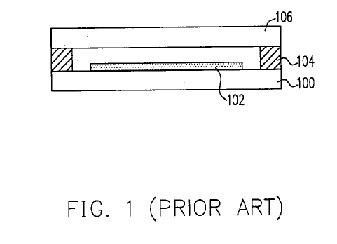

### DETAILED DESCRIPTION

Reference will now be made in detail to the present preferred embodiments of the invention, examples of which are illustrated in the accompanying drawings. Wherever possible, the same reference numbers are used in the drawings and the description to refer to the same or like parts.

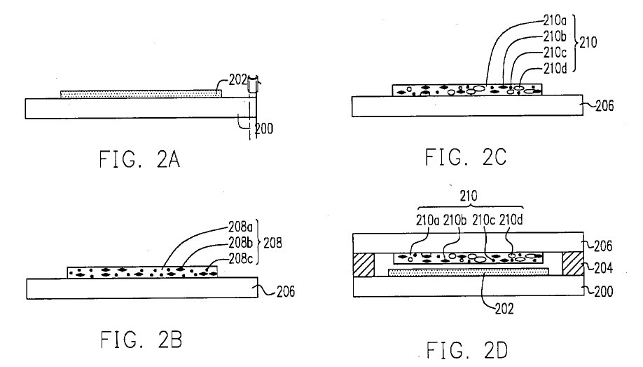

FIGS. 2A to 2D are schematic views showing the steps for producing an OLED package according to a first preferred embodiment of this invention. As shown in FIG. 2A, a substrate 200 having an organic light-emitting film 202 thereon is provided. The OLED film 202 is sandwiched in a pair of electrodes. The OLED film 202 can further comprise an organic electro-luminescent layer, an electron transport layer (ETL), a hole transport layer (HTL), an electron injection layer (EIL) or a hole injection layer (HIL), for example. In addition, the OLED film 202 can be a layer of small molecular organic light-emitting material or a layer of polymer organic light-emitting material.

As shown in FIG. 2B, a cover plate 206 is provided. A layer of liquid desiccant is spread over the cover plate 206 by coating or spraying. The liquid desiccant 208 is a substance comprising a liquid hardening glue 208a and lots of desiccant particles 208b and some vesicant 208c distributed evenly inside the liquid hardening glue 208a. The liquid hardening glue 208a is, for example, a thermosetting material or an ultraviolet hardening material that can be cured by heating or ultraviolet irradiation. The desiccant particles 208b can be made from a material such as barium oxide or other moisture/oxygen absorbing compound. The vesicant 208c can be a liquid vesicant or a solid vesicant made from a material such as cyclo-pentane, fluoro-chloro-carbonate or dinitride compound. In addition, the vesicant 208c are activated to produce gaseous nitrogen or other inert gases and hence numerous of bubbles are performed inside the liquid hardening glue by heating or irradiating the liquid hardening glue with ultraviolet light.

As shown in FIGS. 2B and 2C, the vesicant 208c is activated by heating or irradiating with ultraviolet light and then the liquid hardening glue 208a is cured to form a solidified hardening glue 201a by heating or irradiating with ultraviolet light. Thus, a layer of solidified porous desiccant 210 is formed. Thus, the porous desiccant 210 is a layer containing a mass of solidified hardening glue 210a with lots of bubbles 210d and desiccant particles 210b evenly distributed therein. In general, size of the bubble range between 10 Åto 1 μm. Furthermore, some residual vesicant 210c may remain inside the solidified hardening glue 210a.

In this embodiment, the vesication and the curing process may be integrated according to the following conditions. However, this should not limit the vesication and curing process to heating and irradiating with ultraviolet light.

If the vesicant 208c is activated and the liquid hardening glue 208a cured by heat, the vesication and the curing process can be carried out at the same time. Similarly, if the vesicant 208c is activated and the liquid hardening glue 208a cured by ultraviolet irradiation, the vesication and the curing process can be carried out at the same time. Conversely, if the vesicant 208c is activated by a process that differs from the process for curing the liquid hardening glue 208a, for example, if the vesicant 208c is activated by heat while the liquid hardening glue 208a (an ultraviolet harden material) is cured by ultraviolet irradiation or if the vesicant 208c is activated by ultraviolet irradiation while the liquid hardening glue 208a (a thermoplastic) is cured by heat, the vesication of the vesicant 208c is normally carried out before the curing of the liquid hardening glue 208a.

As shown in FIG. 2D, sealing glue 204 is applied to surrounding edges of the substrate 200 and the cover plate 206 is positioned over the substrate 200. Through the substrate 200, the cover late 206 and the sealing glue 204, the OLED film 202 and the porous desiccant 210 are enclosed inside a sealed compartment. In this embodiment, the porous desiccant 210 contains lots of bubbles 210d. These uniformly distributed bubbles 210d inside the solidified hardening glue 210a speed up the absorption of residual moisture and oxygen inside the sealed compartment by the desiccant particles 210b.

As shown in FIG. 2D, this invention provides an organic light-emitting device (OLED) package. The package is assembled using a number of components including a substrate 200, a cover plate 206, a porous desiccant layer 210 and a sealing glue 204. The substrate 200 has an organic light-emitting film 202 thereon. The cover plate 206 is positioned over the substrate 200. The porous desiccant layer 210 is attached to the surface of the cover plate 206. The porous desiccant layer 210 comprises a mass of solidified hardening glue 210a with plenty of bubbles 210d and numerous desiccant particles 210b evenly distributed therein. The solidified hardening glue 210a may also contain some vesicant 210c. The sealing glue 204 is located between the substrate 200 and the cover plate 206. The substrate 200, the cover plate 206 together with the sealing glue 204 enclose the organic light-emitting thin film 202 and the porous desiccant layer 210.

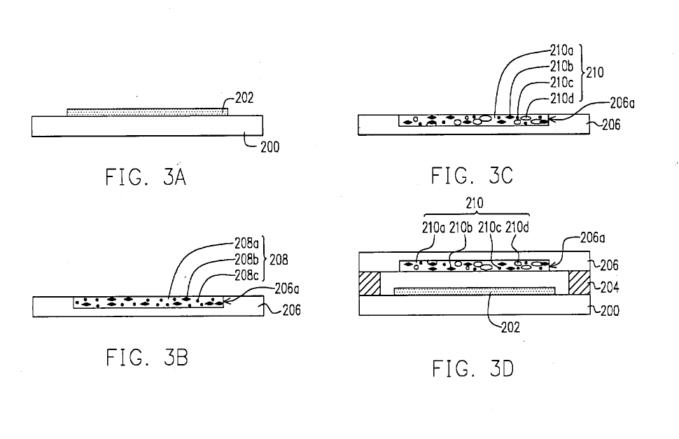

FIGS. 3A to 3D are schematic views showing the steps for producing an alternative OLED package according to the first preferred embodiment of this invention. The process of fabricating an OLED package as shown in FIGS. 3A to 3D differs very little from the process of fabricating the OLED package as shown in FIGS. 2A to 2D except that the liquid desiccant 208 is fabricated inside an additional groove 206a on the cover plate 206. The package structure in FIG. 3D differs from the one in FIG. 2D in that the porous desiccant layer 210 is formed inside the groove 206a so that a package having a smaller thickness can be produced.

In the aforementioned embodiment, the porous desiccant is formed inside an OLED package. However, the porous desiccant and the process of forming porous desiccant according to this invention may be used elsewhere to absorb moisture and oxygen from the surrounding.

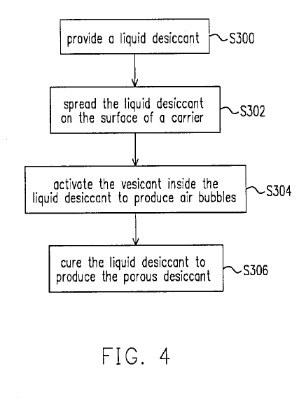

FIG. 4 is a flow chart showing the steps for producing porous desiccant according to one preferred embodiment of this invention. The porous desiccant layer of this invention can be formed over a carrier. First, a liquid desiccant is provided (S300). The liquid desiccant is, for example, a liquid hardening glue with numerous desiccant particles and some vesicant distributed evenly therein. Thereafter, the liquid desiccant is spread on the surface of the carrier (S302). The vesicant is activated to produce lots of bubbles inside the liquid desiccant (S304). Finally, the liquid desiccant is cured to produce a solid porous desiccant layer (S306). After curing, the liquid desiccant is transformed into a mass of solidified hardening glue with lots of bubbles and numerous desiccant particles uniformly distributed therein. In addition, the solidified hardening glue may further contain some residual vesicant.

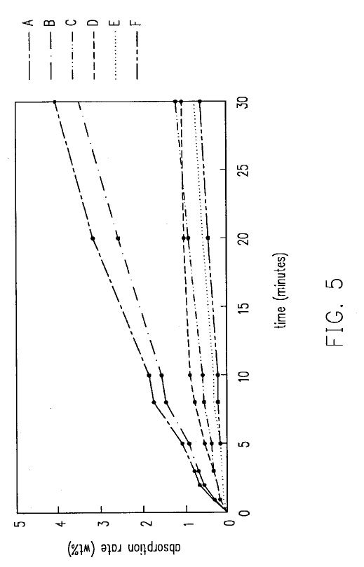

FIG. 5 is a graph showing the relationship between moisture absorbing rate and time for desiccant in different states. Table 1 below lists out the moisture absorption rate for differe types of desiccants. As shown in FIG. 5 and Table 1, samples A, B, C, D and E are different types of desiccant particles (containing barium oxide) with a fixed ratio of ultraviolet materi and vesicant additive. Sample F (equivalent to the desiccant in U.S. Pat. No. 6,226,890) is a ty of desiccant that contains barium oxide particles with ultraviolet material additive. The moisture absorption rate for the samples A˜F is measured after 30 minutes. As shown in FIG. 5, samples A˜E all have an absorption rate better than sample F. Compared with samp F, the porous desiccant fabricated according to this invention has a larger overall contact ar (air bubbles). Therefore, moisture absorption rate improves considerably.

TABLE I

| | | Moisture |
|---|---|---|
| | | absorption |
| Sample | Desiccant composition | rate (wt %) |
| A | Hardening glue + vesicant + desiccant particles 1 | 4 |
| B | Hardening glue + vesicant + desiccant particles 2 | 3.5 |
| C | Hardening glue + vesicant + desiccant particles 3 | 1.2 |
| D | Hardening glue + vesicant + desiccant particles 4 | 1.1 |
| E | Hardening glue + vesicant + desiccant particles 5 | 0.8 |
| F | Hardening glue + barium oxide particles | — |

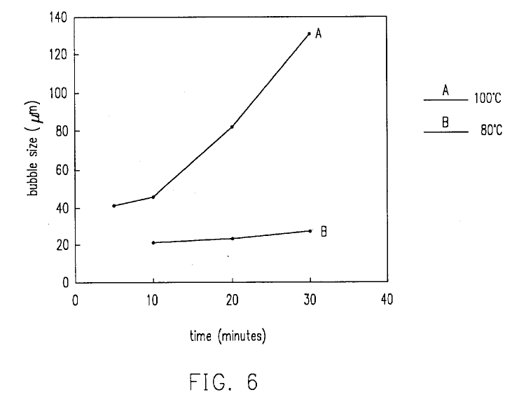

FIG. 6 is a graph showing the relationship between average size of bubble and heating time. The vesicant is activated when subjected to heat or ultraviolet radiation. In general, the result (air bubble size) of vesication depends on timing. The effect of heating temperature and heating time on the average size of air bubbles is shown in FIG. 6. At a temperature of about 80° C. (curve B), average size of air bubbles will barely increase with prolonged heating. However, at a temperature of about 100° C. (curve A), there is considerable increase in average size of air bubbles after heating 10 or more minutes.

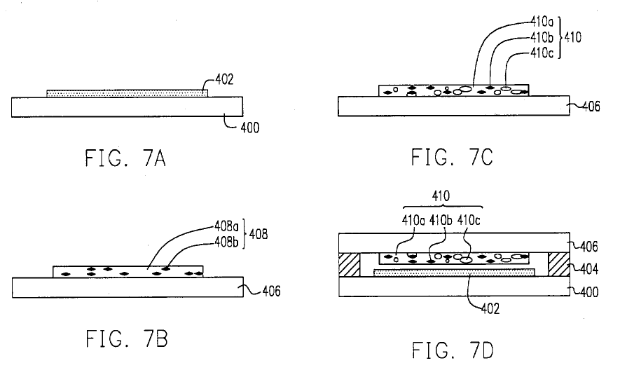

FIGS. 7A to 7D are schematic views showing the steps for producing an OLED package according to a second preferred embodiment of this invention. As shown in FIG. 7A, a substrate 400 having an organic light-emitting film 402 thereon is provided. The OLED film 402 is sandwiched in a pair of electrodes. The OLED film 402 can further comprise an organic electro-luminescent layer, an electron transport layer (ETL), a hole transport layer (HTL), an electron injection layer (EIL) or a hole injection layer (HIL), for example. In addition, the OLED film 402 can be a layer of small molecular organic light-emitting material or a layer of polymer organic light-emitting material.

As shown in FIG. 7B, a cover plate 406 is provided. A layer of liquid desiccant is spread over the cover plate 406 by, for example, coating or spraying. The liquid desiccant 408 is a substance comprising a liquid hardening glue 408a and lots of desiccant particles 408b distributed evenly inside the liquid hardening glue 408a. The liquid hardening glue 408a is, for example, a thermosetting material or an ultraviolet hardening material that can be cured by heating or ultraviolet irradiation. The desiccant particles 408b can be made from a material such as barium oxide or other moisture/oxygen absorbing compound.

As shown in FIGS. 7B and 7C, air is injected or by some other physical means into the liquid desiccant 408 and then the liquid hardening glue 408a is cured to form a solidified hardening glue 410a by heating or irradiating with ultraviolet light. Thus, a layer of solidified porous desiccant 410 is formed. Thus, the porous desiccant layer 410 is a layer containing a mass of solidified hardening glue 410a with lots of bubbles 410c and desiccant particles 410b evenly distributed therein. In general, size of the bubble range between 10 Åto 1 μm.

As shown in FIG. 7D, sealing glue 404 is applied to surrounding edges between the substrate 400 and the cover plate 406. Through the substrate 400, the cover plate 406 and the sealing glue 404, the OLED thin film 402 and the porous desiccant 410 are enclosed. In this embodiment, the porous desiccant 410 contains lots of bubbles 410c. These uniformly distributed bubbles 410c inside the solidified hardening glue 410a speed up the absorption of residual moisture and oxygen inside the sealed compartment by the desiccant particles 410b.

As shown in FIG. 7D, this invention provides an organic light-emitting device (OLED) package. The package is assembled using a number of components including a substrate 400, a cover plate 406, a porous desiccant layer 410 and a sealing glue 404. The substrate 400 has an organic light-emitting film 402 thereon. The cover plate 406 is positioned over the substrate 400. The porous desiccant layer 410 is, for example, attached to the surface of the cover plate 406. The porous desiccant layer 410 comprises a mass of solidified hardening glue 410a with plenty of bubbles 410c and numerous desiccant particles 410b evenly distributed inside the glue 410a. The sealing glue 404 is located between the substrate 400 and the cover plate 406. The substrate 400, the cover plate 406 together with the sealing glue 404 enclose the organic light-emitting thin film 402 and the porous desiccant layer 410.

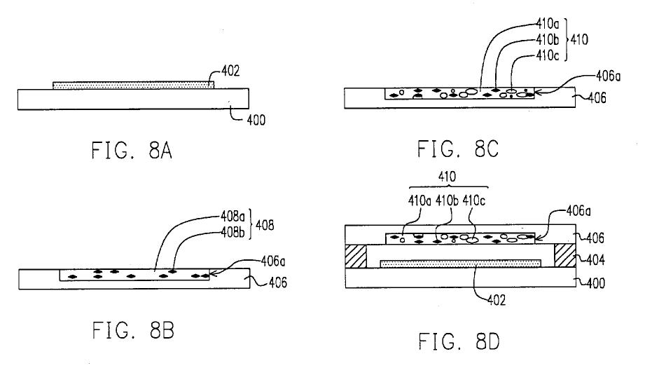

FIGS. 8A to 8D are schematic views showing the steps for producing an alternative OLED package according to the second preferred embodiment of this invention. The process of fabricating an OLED package as shown in FIGS. 8A to 8D differs very little from the process of fabricating the OLED package as shown in FIGS. 7A to 7D except that the liquid desiccant 408 is fabricated inside an additional groove 406a on the cover plate 406. The package structure in FIG. 8D differs from the one in FIG. 7D in that the porous desiccant layer 410 is formed inside the groove 406a so that a package having a smaller thickness can be produced.

In the aforementioned embodiment, the porous desiccant is formed inside an OLED package. However, the porous desiccant and the process of forming porous desiccant according to this invention may be used elsewhere to absorb moisture and oxygen from the surrounding.

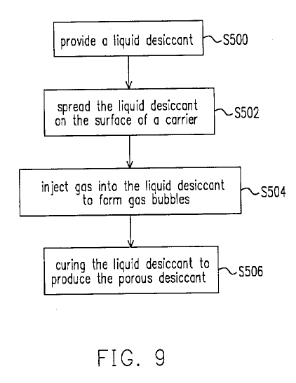

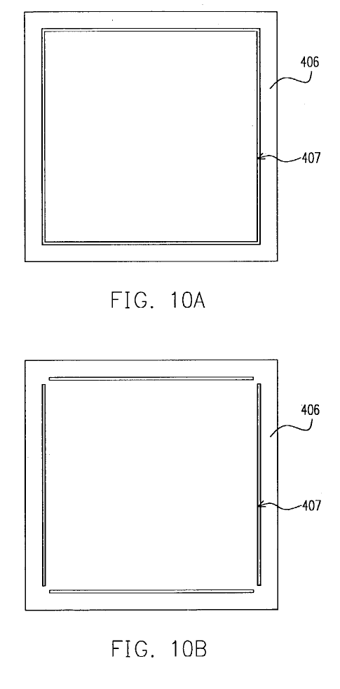

FIG. 9 is a flow chart showing the steps for producing porous desiccant according to the second preferred embodiment of this invention. The porous desiccant layer of this invention can be formed over a carrier. First, a liquid desiccant is provided (S500). The liquid desiccant is, for example, liquid hardening glue with numerous desiccant particles distributed evenly therein. Thereafter, the liquid desiccant is spread on the surface of the carrier (S502). Gas is injected into the liquid desiccant to form bubbles (S504). Finally, the liquid desiccant is cured to produce a solid porous desiccant layer (S506). After curing, the liquid desiccant is transformed into a mass of solidified hardening glue with lots of bubbles and numerous desiccant particles uniformly distributed therein.

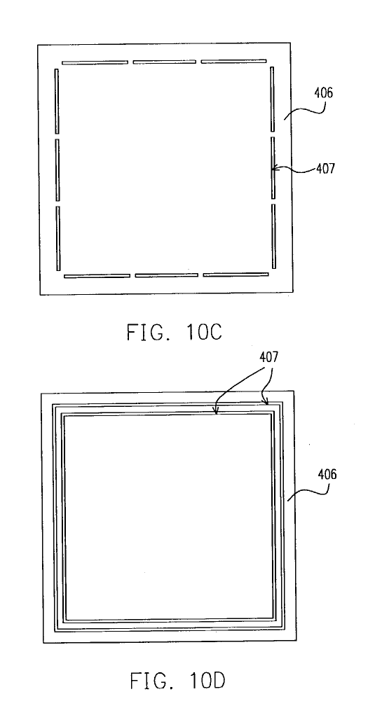

FIGS. 10A to 10D are top views showing the locations and distribution of grooves on the cover plate of an OLED package according to this invention. The grooves on the cover plate 406 can be arranged to form a continuous frame (as shown in FIG. 10A), a plurality of broken lines (as shown in FIGS. 10B and 10C) or a series of continuous frames (as shown in FIG. 10D).

In summary, major advantages of this invention includes:

1. The porous desiccant is capable of rapidly and efficiently absorbing moisture and oxygen leaked into the enclosed chamber or enclosed during a package sealing operation due to considerably increase in moisture/oxygen absorbing area through a vesication process. Consequently, the OLED package has a longer lifetime.

2. Since conducting a liquid desiccant coating, a bubble forming process (for example, a vesication process or a bubble injection process) and a curing process in sequence forms the porous desiccant, other fabricating processes may easily integrate with the production of porous desiccant.

It will be apparent to those skilled in the art that various modifications and variations can be made to the structure of the present invention without departing from the scope or spirit of the invention. In view of the foregoing, it is intended that the present invention cover modifications and variations of this invention provided they fall within the scope of the following claims and their equivalents.;

1. An organic light-emitting device (OLED) package, comprising:
a substrate having at least one organic electro-luminescent thin film thereon;
a cover plate over the substrate;
a porous desiccant layer attached to the cover plate, wherein the porous desiccant layer is a mass of solidified hardening glue with plenty of air bubbles and lots of desiccant particles evenly distributed therein; and
a sealing glue between the substrate and the cover plate, wherein the substrate, the cover plate and the sealing glue together seal up the organic electro-luminescent film and the porous desiccant layer.

2. The OLED package of claim 1, wherein the porous desiccant layer further includes some vesicant evenly distributed inside the solidified hardening glue.

3. The OLED package of claim 2, wherein material constituting the vesicant is selected from a group consisting of cyclo-pentane, fluoro-chloro-carbonate and dinitride compound.

4. The OLED package of claim 2, wherein the vesicant is in a liquid vesicant or a solid vesicant.

5. The OLED package of claim 1, wherein material constituting the desiccant particles or powder includes barium oxide.

6. The OLED package of claim 1, wherein material constituting the solidified hardening glue includes thermosetting material or ultraviolet setting material.

7. The OLED package of claim 1, wherein the cover plate further includes a groove for accommodating the porous desiccant.

8. The OLED package of claim 1, wherein the cover plate further includes a groove for confining the sealing glue within a definite range.

9. A method of forming an organic light-emitting device package, comprising the steps of:
providing a substrate having at least one organic electro-luminescent film thereon;
providing a cover plate;
providing a liquid desiccant, wherein the liquid desiccant is a mass of liquid hardening glue with numerous desiccant particles or powder evenly distributed therein;
spreading the liquid desiccant on the surface of the cover plate;
forming bubbles inside the liquid desiccant;
curing the liquid desiccant to form a solid porous desiccant layer, wherein the porous desiccant layer includes solidified hardening glue with plenty of bubbles therein and numerous desiccant particles or powder within the solidified hardening glue; and
forming a sealing glue layer between the substrate and the cover plate to form a sealed chamber inside the package, wherein the substrate, the cover plate and the sealing glue together seals up the organic electro-luminescent film and the porous desiccant layer within the chamber.

10. The method of claim 9, wherein the bubbles inside the porous desiccant layer is formed by adding vesicants into the liquid desiccant and activating the vesicants.

11. The method of claim 10, wherein material constituting the vesicant is selected from a group consisting of cyclo-pentane, fluoro-chloro-carbonate and dinitride compound.

12. The method of claim 10, wherein the vesicant is activated by heating the liquid desiccant or irradiating the liquid desiccant with ultraviolet light.

13. The method of claim 10, wherein the activation of the vesicant and the curing of the liquid hardening glue are carried out concurrently.

14. The method of claim 10, wherein the vesicant is activated before curing the liquid hardening glue.

15. The method of claim 9, wherein the bubbles within the liquid desiccant is formed by injecting gas into the liquid desiccant.

16. The method of claim 15, wherein the step of injecting gas into the liquid desiccant to form air bubbles includes injecting inert gas.

17. A type of porous desiccant, comprising:
a mass of solidified hardening glue with lots of bubbles therein; and
desiccant particles or powder distributed evenly inside the solidified hardening glue.

18. The desiccant of claim 17, wherein the porous desiccant further comprises some vesicant distributed evenly inside the solidified hardening glue.

19. The desiccant of claim 18, wherein material constituting the vesicant is selected from a group consisting of cycle-pentane, fluoro-chloro-carbonate and dinitride compound.

20. The desiccant of claim 18, wherein the vesicant is in a liquid vesicant or a solid vesicant.

21. The desiccant of claim 17, wherein material constituting the desiccant particles or powder includes barium oxide.

22. The desiccant of claim 17, wherein material constituting the solidified hardening glue includes thermosetting material or ultraviolet setting material.

23. A method of forming porous desiccant, comprising the steps of:
providing a liquid desiccant, wherein the liquid desiccant is a mass of liquid hardening material with numerous desiccant particles distributed evenly therein;
spreading the liquid desiccant on the surface of a carrier; and
forming bubbles inside the liquid desiccant and curing the liquid desiccant to form a porous desiccant layer, wherein the porous desiccant layer mainly includes solidified hardening glue with plenty of bubbles therein and numerous desiccant particles or powder within the solidified hardening glue.

24. The method of claim 23, wherein the bubbles inside the liquid desiccant are formed by adding vesicant into the liquid desiccant and activating the vesicant.

25. The method of claim 24, wherein material constituting the vesicant is selected from a group consisting of cyclo-pentane, fluoro-chloro-carbonate and dinitride compound.

26. The method of claim 24, wherein the vesicant is activated by heating the liquid desiccant or irradiating the liquid desiccant with ultraviolet light.

27. The method of claim 24, wherein the activation of the vesicant and the curing of the liquid hardening glue are carried out concurrently.

28. The method of claim 24, wherein the vesicant is activated before curing the liquid hardening glue.
